(19) United States
(12) Patent Application Publication
(10) Pub. No.: US 2016/0035766 A1
(43) Pub. Date: Feb. 4, 2016

(54) SEMICONDUCTOR DEVICE AND MANUFACTURING METHOD THEREOF

(71) Applicant: KABUSHIKI KAISHA TOSHIBA, Tokyo (JP)

(72) Inventors: Satoshi HONGO, Oita Oita (JP); Tsuyoshi MATSUMURA, Oita Oita (JP); Hiroaki ASHIDATE, Oita Oita (JP); Kazumasa TANIDA, Oita Oita (JP)

(21) Appl. No.: 14/624,221

(22) Filed: Feb. 17, 2015

(30) Foreign Application Priority Data
Aug. 1, 2014 (JP) 2014-158065

(51) Int. Cl. H01L 27/146

(52) U.S. Cl. CPC H01L 27/1461; H01L 27/14621; H01L 27/14627; H01L 27/14636; H01L 27/14685; H01L 27/14645; H01L 27/14689

(57) ABSTRACT

A semiconductor device such as, for example an imaging sensor, includes a semiconductor layer in which, for example, a photodiode may be formed. An insulation film is disposed on a surface of the semiconductor layer. The insulation film includes one or more wirings or wiring layers formed therein. A semiconductor support substrate is disposed on the insulation film. The semiconductor support substrate includes a first layer (or region) and a second layer (or region) that is between the insulation film and the first layer. The first layer has a bulk micro defect density that is higher than a bulk micro defect density of the second layer.

### CROSS-REFERENCE TO RELATED APPLICATION

This application is based upon and claims the benefit of priority from Japanese Patent Application No. 2014-158065, filed Aug. 1, 2014, the entire contents of which are incorporated herein by reference.

### FIELD

Embodiments described herein relate generally to a semiconductor device and a manufacturing method thereof.

### BACKGROUND

Conventionally, a back surface emission type CMOS image sensor is fabricated through a step of grinding and polishing a semiconductor substrate that has a semiconductor layer into which photoelectric conversion elements are formed, the step of grinding and polishing a semiconductor substrate following a step of bonding the semiconductor substrate and a semiconductor support substrate. The semiconductor substrate can be reduced to a thin film after the lamination process.

However, in the laminating process, a stress is applied to the semiconductor substrate on which the photoelectric conversion elements are formed. Accordingly, there may be a case where a deformation or strains are generated in the semiconductor substrate. Due to such deformation or strains, misalignment may be generated between a position of micro lenses provided on the back surface emission type CMOS image sensor and the position of the photoelectric conversion elements, which causes deterioration of characteristics of the back surface emission type CMOS image sensor. That is, deformation or strain resulting from the lamination process may cause the optical axis of a microlens to be offset from on intended position (e.g., a centerline of the conversion element) above the photoelectric conversion element

### DESCRIPTION OF THE DRAWINGS

FIG. 1 is a view schematically showing a cross section of a semiconductor device according to a first embodiment;

FIGS. 2A to 2G are views showing one method of manufacturing the semiconductor device according to the first embodiment; and

FIGS. 3A to 3C are views showing one embodiment of the manufacture of a semiconductor support substrate which has a bulk micro defect layer.

### DETAILED DESCRIPTION

In general, according to one embodiment, a semiconductor device includes a semiconductor layer, an insulation film, and a semiconductor substrate support. The insulation film is formed on a surface of the semiconductor layer, and the insulation film includes one or more wirings. The semiconductor support substrate is disposed on the insulation film. The semiconductor support substrate includes a first layer (or region) and a second layer (or region). A bulk micro defect density in the first layer is higher than a bulk micro defect density in the second layer. The second layer is between the insulation film and the first layer.

Hereinafter, exemplary semiconductor devices and exemplary methods of manufacturing these semiconductor devices according to several embodiments are explained with reference to attached drawings. However, the present disclosure is not limited by these embodiments.

### First Embodiment

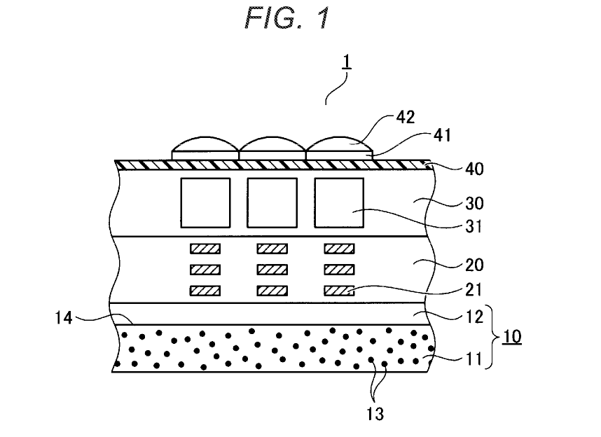

FIG. 1 is a view schematically showing a cross section of a semiconductor device according to the first embodiment. The semiconductor device 1 of this embodiment includes a semiconductor support substrate 10. The semiconductor support substrate 10 is a silicon substrate, for example, and includes a bulk micro defect (BMD) layer 11 (first layer) and a layer 12 (second layer) where bulk micro defects are not substantially present. The bulk micro defects are typically mainly oxygen precipitates. For example, a majority or more of the bulk micro defects in the layers 11, 12 can be oxygen precipitates. In some instances, layer 12 may have a bulk micro defect density which is negligible and/or difficult to detect. The bulk micro defects may also be carbon precipitates or the like instead of or in addition to oxygen precipitates. For example, as shown in FIG. 1 the bulk micro defect layer 11 has bulk micro defects 13. The bulk micro defect density can be between about 0.01×10⁹ pieces/cm³ to about 1000×10⁹ pieces/cm³. In this context, “bulk micro defect density” refers to an average concentration of defects throughout the respective layer or within a representative portion of the respective layer. The concentration of precipitates may vary from the bulk micro defect density in sub-regions of the respective layer. A boundary line between the bulk micro defect layer 11 and the layer 12 where bulk micro defects are not substantially present is indicated by a boundary line 14 for the sake of convenience, but the local micro defect density may be substantially similar in layer regions directly adjacent to the boundary line 14. The layer 12 where bulk micro defects are not substantially present is a layer (or region) which may be defined as a layer (or region) where bulk micro defect density is lower than 0.01×10⁹ pieces/cm³, for example. The bulk micro defect density in the bulk micro defect layer 11 is greater than the average bulk micro defect density in the layer 12. In some embodiments, the average bulk micro defect density in the bulk micro defect layer 11 is between about 1000 and about 100,000 times than the average bulk micro defect density in the layer 12. Bulk micro density values can be acquired by observing or measuring a wafer cross-section using a transmission electron microscope (TEM), a crystal defect inspection apparatus or the like.

An insulation film 20 is formed on the semiconductor support substrate 10. The insulation film 20 is formed of a silicon oxide film, for example. Predetermined lines (wiring) 21 are formed within the insulation film 20. The wirings 21 are formed of a metal film, for example.

A semiconductor layer 30 is formed on the insulation film 20. Photoelectric conversion elements 31 are formed in the semiconductor layer 30. The photoelectric conversion elements 31 are photo diodes, for example.

A protective film 40 is formed on the semiconductor layer 30. The protective film 40 is formed of a silicon oxide film or a silicon nitride film, for example. Color filters 41 are formed on the protective film 40. Each color filter 41 allows only one of red (R), green (G) and blue (B) to transmit through the respective color filter, for example. The color filters 41 are disposed corresponding to the respective photoelectric conversion elements 31.

Micro lenses 42 are formed on the color filters 41 corresponding to the photoelectric conversion elements 31. Each micro lens 42 has a spherical surface (or a curved surface), and converges incident light to the corresponding photoelectric conversion element 31.

According to this first embodiment, the semiconductor support substrate 10 has the bulk micro defect layer 11. The bulk micro defect layer 11 can have a bulk micro defect density between about 0.01×10⁹ pieces/cm³ to about 1000×10⁹ pieces/cm³, for example. The semiconductor support substrate 10 having the bulk micro defect layer 11 is laminated to the insulation film 20, which includes the wirings 21 formed inside, for example. By using the substrate having the bulk micro defect layer 11 as the semiconductor support substrate 10 for the semiconductor device 1, the strains in the semiconductor layer 30 are reduced. For example, because of the reduction of strains in the semiconductor layer 30, the result is acquired where an average value of an amount of displacement between an optical axis of the micro lens 42 and the center (centerline along a direction approximately normal to the plane of semiconductor support substrate 10) of the corresponding photoelectric conversion element 31 is improved by approximately 20% to 30%. It is considered (without being limited to any specific mechanism) that the bulk micro defect layer 11 of the semiconductor support substrate 10 performs a function as a buffer material resulting to reduce strains in the semiconductor layer 30 when the semiconductor support substrate 10 is bonded to the insulation film 20. When bulk micro defect density of the bulk micro defect layer 11 becomes excessively high, the strength of the semiconductor support substrate 10 is lowered to become a cause of “chipping” where the semiconductor support substrate 10 is chipped or damaged in an assembling step that is performed later. In view of the above, the bulk micro defect density of the semiconductor support substrate 10 is selected by considering a function of the bulk micro defect layer 11 as a buffer material at the time of wafer bonding and necessary strength of the semiconductor support substrate 10 required to limit or avoid “chipping” in subsequent process steps, for example.

### Second Embodiment

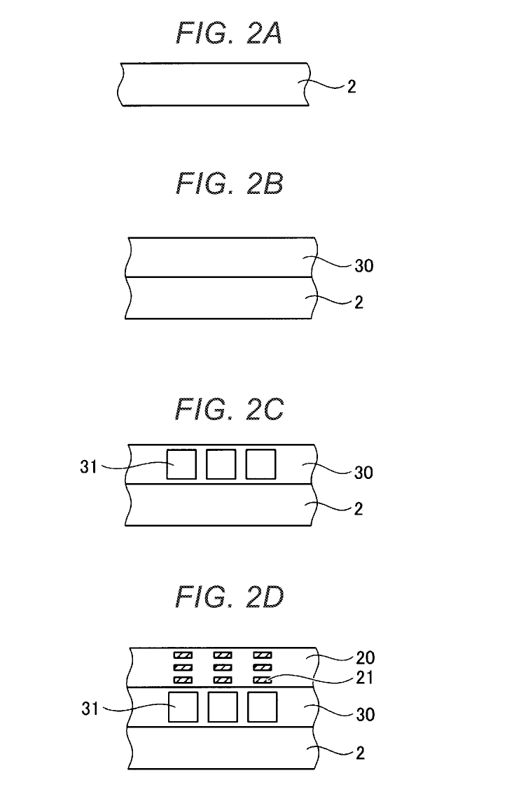

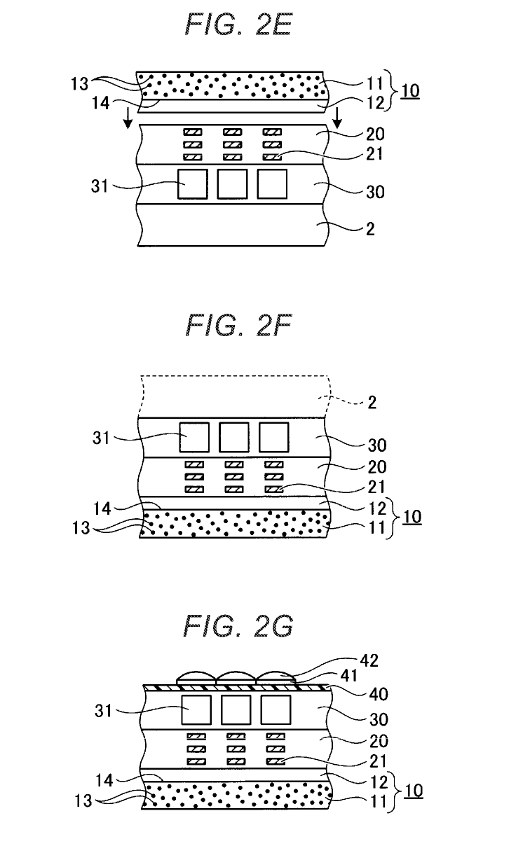

Next, one method of manufacturing the semiconductor device 1 according to the first embodiment is explained with reference to FIGS. 2A to 2G. Elements in FIG. 2A to 2G corresponding to elements of the first embodiment are given the same symbols.

A semiconductor substrate 2 is prepared (FIG. 2A). The semiconductor substrate 2 is a silicon substrate, for example.

The semiconductor layer 30 is formed on a surface of the semiconductor substrate 2 (FIG. 2B). The semiconductor layer 30 is formed by an epitaxial growth method. For example, the semiconductor layer 30 is formed by a CVD (Chemical Vapor Deposition) method. The semiconductor layer 30 has a film thickness of approximately 5 μm, for example.

Steps referred to as an FEOL (Front End of Line) such as a lithography step, a film forming step, an etching step, and an ion injecting step are repeatedly applied to the semiconductor layer 30 to form a photoelectric conversion element 31, for example (FIG. 2C). The photoelectric conversion element 31 is a photo diode, for example.

Next, an insulation film 20 that includes wirings 21 for electrical connections is formed in steps referred to as a BEOL (Back End of Line) (FIG. 2D). The wirings 21 formed in the insulation film 20 are formed of Cu lines having the damascene structure. The insulation film 20 which covers the wirings 21 is an oxide film formed by using TEOS (Tetra Ethyl Ortho Silicate) as a raw material.

A semiconductor support substrate 10 is laminated to the insulation film 20 (FIG. 2E). The semiconductor support substrate 10 includes a bulk micro defect layer 11 and a layer 12 where bulk micro defects are not substantially present. The bulk micro defect layer 11 has a bulk micro defect density of between about 0.01×10 pieces/cm³ to about 1000×10⁹ pieces/cm³, for example. The bulk micro defect layer 11 and the layer 12 where bulk micro defects are not substantially present are indicated in by using a boundary line 14 for the sake of convenience. A side (surface) of the layer 12 in the semiconductor support substrate 10 is laminated (bonded) to the insulation film 20. By bonding the layer 12 side of the semiconductor support substrate 10 to the insulation film 20, joining strength is increased because layer 12 has substantially no (or very low) bulk micro defect density. By using a clean surface where the bulk micro defects are not substantially present as a lamination joining surface, lamination joining strength will be increased. In the bonding step of bonding the semiconductor support substrate 10 to the insulation film 20, a step of cleaning the joining surface, a step of activating the joining surface and the like are performed. Thereafter, the semiconductor support substrate 10 is aligned with the insulation film 20, and the lamination of the semiconductor support substrate 10 is performed using a substrate adhesion technique.

Thereafter, the semiconductor substrate 2 is removed (FIG. 2F). For the sake of convenience, the semiconductor substrate 2 and the semiconductor support substrate 10 are shown in an upside down state. The step of removing the semiconductor substrate 2 can be performed by combining wet etching and CMP (Chemical Mechanical Polishing) with each other, for example. That is, the semiconductor substrate 2 is etched to some extent by wet etching and, thereafter, the semiconductor substrate 2 is removed by CMP.

Subsequently, a protective film 40 is formed on a semiconductor layer 30. The protective film 40 is formed of a silicon oxide film or a silicon nitride film, for example. The protective film 40 is formed by a CVD method, for example. Color filters 41 and micro lenses 42 are formed on the protective film 40 (FIG. 2G).

According to a method of manufacturing the semiconductor device 1, the semiconductor support substrate 10 having the bulk micro defect layer 11 is bonded to the insulation film 20 that includes the wirings 21 formed inside. The bulk micro defect layer 11 of the semiconductor support substrate 10 performs a function of the buffer material at the time of laminating the semiconductor support substrate 10 and hence, strains in the semiconductor layer 30 are reduced. The bulk micro defect layer 11 has a bulk micro defect density of between about 0.01×10⁹ pieces/cm³ to about 1000×10⁹ pieces/cm³, for example.

By making a crystal azimuth (direction normal to the crystal plane) of the semiconductor support substrate 10 and a crystal azimuth of the semiconductor layer 30 substantially agree with each other, a stress generated due to the difference in Young's modulus along different crystal planes is reduced. Accordingly, it is possible to reduce strains generated in the semiconductor layer 30 due to a stress attributed to a crystal azimuth difference between layers. The semiconductor layer 30 is formed on a surface of the semiconductor substrate 2 by an epitaxial growth method, for example. Accordingly, by making the crystal azimuth of the semiconductor substrate 2 and the crystal azimuth of the semiconductor support substrate 10 agree with each other, it is possible to make the crystal azimuth of the semiconductor layer 30 and the crystal azimuth of the semiconductor support substrate 10 also agree with each other. By bonding the semiconductor support substrate 10 having a main surface in a specific crystal plane orientation, for example, in a (100) plane and aligning the semiconductor substrate 2 to have a main surface of the substrate 2 in same specific crystal plane, such as the (100) plane, the crystal azimuth of the semiconductor support substrate 10 and the crystal azimuth of the semiconductor substrate 2 are made agree to each other and, consequently, the crystal plane orientations (X direction, Y direction, Z direction) of the semiconductor support substrate 10 and the crystal plane orientations (X direction, Y direction, Z direction) of the semiconductor layer 30 are made to agree with each other.

An oxide film (not shown in the drawing) may be formed on a surface of the semiconductor support substrate 10 bonded to the insulation film 20. That is, the oxide film is formed on the surface of the semiconductor support substrate 10 before the bonding is performed and, thereafter, the bonding between the semiconductor support substrate 10 and the insulation film 20 is performed. Alternatively, a nitride film (not shown in the drawing) may be formed on the surface of the semiconductor support substrate 10 in place of the oxide film.

The explanation has been made with respect to the embodiment where the photoelectric conversion element 31 is formed on the semiconductor layer 30 which has been formed on the surface of the semiconductor substrate 2 by an epitaxial growth method. However, in some embodiments the photoelectric conversion element 31 may be formed on a region of the surface of the semiconductor substrate 2. That is, the region of the surface of the semiconductor substrate 2 may be formed as a semiconductor layer on which the photoelectric conversion element 31 is formed. In this case, after the semiconductor support substrate 10 is bonded to the insulation film 20, for example, the semiconductor substrate 2 is polished to decrease a thickness of the semiconductor substrate 2 up to the region of the surface of the semiconductor substrate 2 on which the photoelectric conversion element 31 is formed.

### Third Embodiment

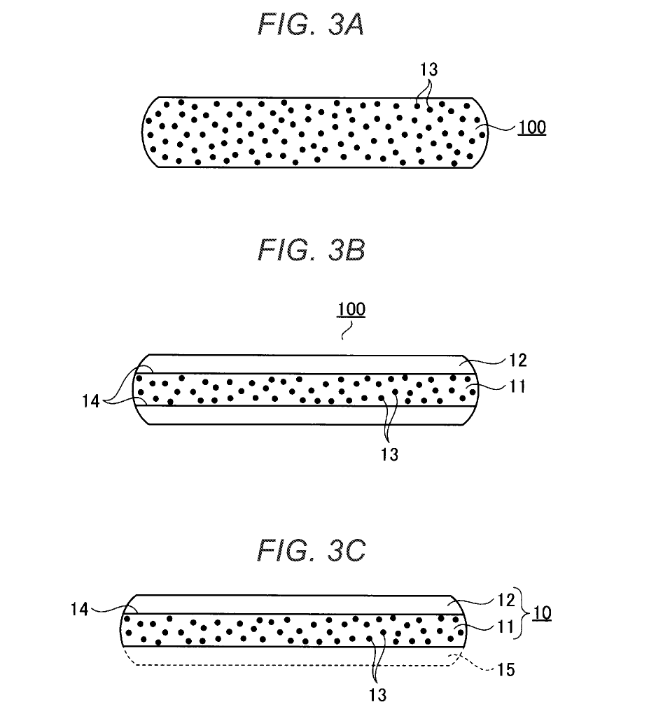

FIGS. 3A to 3C are views showing one embodiment of manufacturing a semiconductor support substrate 10 having a bulk micro defect layer 11. Elements in FIG. 3A to 3C corresponding to elements in the previous Figures are given the same symbols.

Firstly, a semiconductor wafer 100 having bulk micro defects 13 is prepared (FIG. 3A).

Next, heat treatment is applied to the semiconductor wafer 100 in an inert gas atmosphere at a temperature of 1100° C. or higher. Due to this heat treatment, the bulk micro defect layer 11 where bulk micro defects 13 are present and the layer 12 where the bulk micro defects 13 are not substantially present are formed in the semiconductor wafer 100 (FIG. 3B). That is, oxygen present in a front surface layer of the semiconductor wafer 100 is discharged to the outside due to the heat treatment so that a layer where oxygen precipitates, which are main configuration elements of the bulk micro defects 13, are not present on the front surface layer of the semiconductor wafer 100. Since oxygen precipitates which are main configuration elements of the bulk micro defects 13 are not present, the layer 12 where the bulk micro defects 13 are not substantially present is formed on the front surface layer of the semiconductor wafer 100. On the other hand, oxygen concentration is maintained in the inside of the semiconductor wafer 100 and hence, the bulk micro defect layer 11 is formed, where the bulk micro defects 13 which precipitate as oxygen precipitates are present. A boundary line 14 between the bulk micro defect layer and the layer 12 is indicated for the sake of convenience.

A region 15 on a back surface side of the semiconductor wafer 100 is removed (FIG. 3C). The semiconductor support substrate 10 is formed by removing the region 15. The semiconductor wafer 100 may be used as the semiconductor support substrate 10 without removing the region 15 on the back surface side. The bulk micro defect density may be controlled by adjusting oxygen (or carbon) concentration in the semiconductor wafer 100, for example. Bulk micro density values can be acquired by observing or measuring a cross section of the semiconductor wafer 100 with a physical analysis technique such as transmission electron microscopy (TEM), or with a crystal defect inspection apparatus or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
a semiconductor layer;
an insulation film disposed on a surface of the semiconductor layer, the insulation film including a wiring formed therein; and
a semiconductor support substrate disposed on the insulation film, the semiconductor support substrate including a first layer and a second layer between the insulation film and the first layer, the first layer having a bulk micro defect density that is higher than a bulk micro defect density of the second layer.

2. The semiconductor device according to claim 1, wherein the semiconductor layer includes a photodiode formed therein.

3. The semiconductor device according to claim 2, further comprising:
a microlens disposed on the semiconductor layer in positional correspondence with the photodiode.

4. The semiconductor device according to claim 1, wherein the bulk micro defect density in the second layer is less than 0.01×10⁹ pieces/cm³, and the bulk micro defect density of the first layer is greater of equal to 0.01×10⁹ pieces/cm³ and less than or equal to about 1000×10⁹ pieces/cm³.

5. The semiconductor device according to claim 1, wherein the bulk micro defect density of the second layer is less than about 0.01×10⁹ pieces/cm³.

6. The semiconductor device according to claim 1, wherein bulk micro defects in the first and second layers are oxygen precipitates.

7. The semiconductor device according to claim 1, further comprising:
a color filter disposed on the semiconductor layer; and
a microlens disposed on the color filter, wherein
the color filter is between the semiconductor layer and the microlens.

8. An imaging device, comprising:
a semiconductor layer including a photodiode formed therein, the semiconductor layer having first and second sides;
an insulation film disposed on the second side of semiconductor layer, the insulating film including a wire formed therein; and
a support substrate laminated to the insulation film such that the insulation film is between the semiconductor layer and the support substrate, the support substrate including first and second regions, the second region being adjacent to insulation film and between the first region and the insulation film, the second region having a bulk micro defect density that is less than a bulk micro defect density of the first region.

9. The imaging device according to claim 8, further comprising a microlens disposed on the first side of the semiconductor layer in alignment with the photodiode.

10. The imaging device according to claim 8, wherein bulk micro defects in the support substrate comprise oxygen precipitates.

11. The imaging device according to claim 8, wherein the bulk micro defect density of the second region is less than 0.01×10⁹ pieces/cm³.

12. The imaging device according to claim 8, wherein the average density of oxygen precipitate of the first region is between about 0.01×10⁹ pieces/cm³ and about 1000×10⁹ pieces/cm³.

13. The imaging device according to claim 8, wherein values of the bulk micro defect density for the first and second regions are determined by transmission electron microscopy.

14. A method of manufacturing a semiconductor device, comprising:
forming a semiconductor layer on a first semiconductor substrate; and
laminating a second semiconductor substrate to the first semiconductor substrate, the second semiconductor substrate including first and second regions, the first region having a bulk micro density that is greater than a bulk micro defect density in the second region, the second region being between the first region and the first semiconductor substrate after lamination.

15. The method according to claim 14, wherein a photoelectric conversion element is formed in the semiconductor layer before laminating the second semiconductor substrate to the first semiconductor substrate.

16. The method according to claim 15, further comprising forming a microlens on the first semiconductor substrate in alignment with the photoelectric conversion element.

17. The method according to claim 14, wherein a crystal plane orientation of the first semiconductor substrate and a crystal plane orientation of the second semiconductor substrate are aligned during the laminating of the second semiconductor substrate to the first semiconductor substrate.

18. The method according to claim 14, wherein
the bulk micro defect density of the first region is between about 0.01×10⁹ pieces/cm³ and about 1000×10⁹ pieces/cm³, and
the bulk micro defect density of the second region is less than about 0.01×10⁹ pieces/cm³.

19. The method according to claim 14, wherein an insulation layer is disposed on the first semiconductor substrate such that the insulation layer is between the semiconductor layer and the second semiconductor substrate after laminating the second semiconductor substrate to the first semiconductor substrate.

20. The method according to claim 14, further comprising:
forming a photoelectric conversion element in the semiconductor layer;
forming a color filter on the semiconductor layer in positional correspondence with the photoelectric conversion element; and
forming a microlens on the color filter in positional correspondence with the photoelectric conversion element.
